(19) United States
(12) Patent Application Publication
(10) Pub. No.: US 2013/0313696 A1
(43) Pub. Date: Nov. 28, 2013

(54) POWER SEMICONDUCTOR PACKAGE AND METHOD OF MANUFACTURING THE SAME

(71) Applicant: NIKO SEMICONDUCTOR CO., LTD., New Taipei City (TW)

(72) Inventors: Chih-Cheng HSIEH, New Taipei City (TW); Chung-Ming LENG, New Taipei City (TW)

(73) Assignee: NIKO SEMICONDUCTOR CO., LTD., New Taipei City (TW)

(21) Appl. No.: 13/684,171

(22) Filed: Nov. 22, 2012

(30) Foreign Application Priority Data
May 23, 2012 (TW) 101118359
Oct. 16, 2012 (TW) 101138093

(51) Int. Cl. H01L 23/34; H01L 21/50

(52) U.S. Cl. CPC H01L 23/34; H01L 21/50
USPC 257/675; 438/108

(57) ABSTRACT

A power semiconductor package and a method of method of manufacturing the same are disclosed, where the power semiconductor package includes a lead frame, a first die, a second die and a single connecting strip. The lead frame includes a voltage plate, a grounding plate, an output plate, a first gate plate and a second gate plate. The first die is disposed on the voltage plate, and a high side transistor within the first die is connected to the first gate plate. The second die is disposed on the grounding plate, and a low side transistor within the second die is connected to the second gate plate. The connecting strip is disposed on the first and second dies and the output plate and electrically connects to a source of the high side transistor and a drain of the low side transistor.

### RELATED APPLICATIONS

This application claims priority to Taiwan Application Serial Number 101118359, filed May 23, 2012, and Taiwan Application Serial Number 101138093, filed Oct. 16, 2012, which are herein incorporated by references.

### BACKGROUND

1. Technical Field

The present disclosure relates to packaging technology, and more particularly, semiconductor-packaging technology.

2. Description of Related Art

Recently, with the progression of the industry and commerce and the advancements in human society, the products on the market are aimed to be convenient, accurate, and economical. Therefore, the products that are developed are better than the old products and make contributions to the society.

Power transistors have the advantages of high integrated density, extremely low static leakage current, and increasing power capacity; hence, they have been widely used in various power electronic fields such as power switches and frequency converters. However, as the demand for a compact and slim package with high-integrated density has created, the demand for a better heat dissipation property is increased in the market.

In view of the foregoing, there still exist some inconveniences and defects in conventional packaging structures of power semiconductors that wait further improvement. However, those skilled in the art sought vainly for a solution. In order to solve or circumvent above problems and disadvantages, there is an urgent need in the related field to provide a compact package size with effective heat dissipation capability.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one or more various aspects, the present disclosure is directed to a power semiconductor package and a method of method of manufacturing the same.

According to one embodiment of the present invention, a power semiconductor package includes a lead frame, a first die, a second die and a single connecting strip. The lead frame has a voltage plate, a ground plate, an output plate, a first gate plate and a second gate plate separated from each other. The first die is disposed on the voltage plate, where the first die has a high-side power transistor disposed therein, and a gate of the high-side power transistor is connected to the first gate plate. The second die is disposed on the ground plate, where the second die has a low-side power transistor disposed therein, and a gate of the low-side power transistor is connected to the second gate plate. The connecting strip is disposed on the first die, the second die and the output plate, and is electrically connected to a source of the high-side power transistor and a drain of the low-side power transistor.

The second die is mounted on the ground plate by flip-chip bonding.

The gate of the high-side power transistor is connected to the first gate plate by wire bonding.

The power semiconductor package further includes an encapsulating layer. The first die and the second die are covered with the encapsulating layer.

The connecting strip is a single metal clip adhered to the first die, the second die and the output plate.

A top of the metal clip is exposed to outside the encapsulating layer and the power semiconductor package further includes a heat dissipation plate. The heat dissipation plate is in direct contact with the top of the metal clip.

Moreover, the connecting strip has a location hole.

Alternatively, the connecting strip is a single aluminium strip. The aluminium strip is connected to the first die, the second die and the output plate by thermal compression bonding.

The first gate plate and the second gate plate are positioned at two opposite sides of the first and second dies.

The first gate plate and the second gate plate are positioned along the same side of the first and second dies.

The power semiconductor package further includes a driving chip. The driving chip is connected to the first gate plate and the second gate plate.

According to another embodiment of the present invention, a method of manufacturing a power semiconductor package is provided, and the method includes steps of: providing a lead frame having a voltage plate, a ground plate, an output plate, a first gate plate and a second gate plate; positioning a first die disposed on the voltage plate; positioning a second die disposed on the ground plate, and connecting a gate of a low-side power transistor of the second die to the second gate plate; positioning a single connecting strip on the first die, the second die and the output plate, and electrically connecting the connecting strip to a source of the high-side power transistor and a drain of the low-side power transistor; and connecting a gate of a high-side power transistor of the first die to the first gate plate.

The second die is mounted on the ground plate by flip-chip bonding.

The step of positioning the single connecting strip includes: providing a single metal clip as the connecting strip, and adhering the metal clip to the first die, the second die and the output plate.

The step of positioning the single connecting strip includes: providing a single aluminium strip as the connecting strip, and connecting the single aluminium strip to the first die, the second die and the output plate by thermal compression bonding.

Technical advantages are generally achieved, by embodiments of the present invention, as follows:
1. The voltage plate and the ground plate can be adequately utilized for heat dissipation;
2. The first die and the second die are connected without using a plurality of bonding wires such that an inter-die distance can be very short, so as to allow putting a large-size die and to decrease the processes of wire bonding;
3. The top of the first die and the top of the second die with common electrical potential can be electrically connected through a single metal clip or a single aluminium strip, so as to improve heat dissipation, reduce line inductance and increase a working frequency;
4. A one-piece plate having metal clips can be designed for a plurality of power semiconductor packages in pre-production, so as to reduce manufacturing time;
5. The dies are covered with the encapsulating layer to prevent moisture from corroding the dies for improving reliability; and
6. The power semiconductor package has a double-sided cooling effect.

Many of the attendant features will be more readily appreciated, as the same becomes better understood by reference to the following detailed description considered in connection with the accompanying drawings.

### BRIEF DESCRIPTION OF THE DRAWINGS

The present description will be better understood from the following detailed description read in light of the accompanying drawing, wherein:

FIG. 1 is a circuit diagram of a synchronous rectifier configuration according to one embodiment of the present disclosure;

FIG. 2 is a pictorial drawing of a power semiconductor package according to one embodiment of the present disclosure;

FIG. 3 is a lateral view of FIG. 2 according to one embodiment of the present disclosure;

FIG. 4 is a lateral view of FIG. 2 according to another embodiment of the present disclosure;

FIG. 5 is a lateral view of FIG. 2 according to yet another embodiment of the present disclosure;

FIG. 6 is a partial schematic diagram of a one-piece plate having a plurality of metal clips according to one embodiment of the present disclosure;

FIG. 7 is a pictorial drawing of the power semiconductor package according to another embodiment of the present disclosure;

FIG. 8 is a pictorial drawing of the power semiconductor package according to yet another embodiment of the present disclosure;

FIG. 9 is a lateral view of FIG. 7 according to one embodiment of the present disclosure;

FIG. 10 is a top view of the power semiconductor package according to another embodiment of the present disclosure; and

FIG. 11 is a schematic diagram of a method of manufacturing the power semiconductor package according to another embodiment of the present disclosure.

### DETAILED DESCRIPTION

In the following detailed description, for purposes of explanation, numerous specific details are set forth in order to attain a thorough understanding of the disclosed embodiments. It will be apparent, however, that one or more embodiments may be practiced without these specific details. In other instances, well-known structures and devices are schematically shown in order to simplify the drawing.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

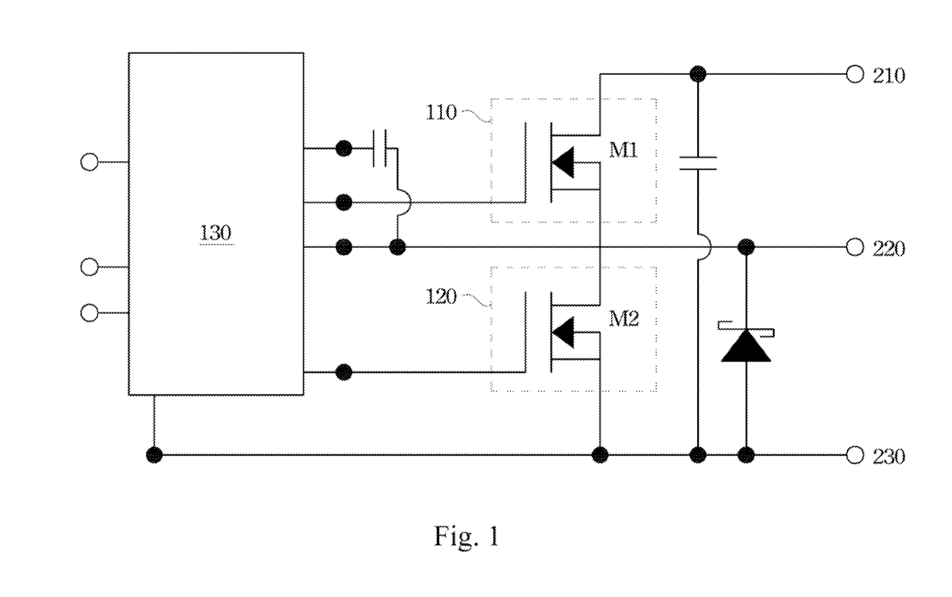

In one aspect, the present disclosure is directed to a power semiconductor package. This power semiconductor package may be easily inserted into the synchronous rectifier configuration and may be applicable or readily adaptable to all technologies. FIG. 1 is a circuit diagram of the synchronous rectifier configuration according to one embodiment of the present disclosure. As shown in FIG. 1, the synchronous rectifier configuration includes a first die 110 and a second die 120. The first die 110 has a high-side power transistor M1 disposed therein. The second die 120 has a low-side power transistor M2 disposed therein. The driving chip 130 alternately controls on/off states of the transistors M1 and M2 for accomplishing synchronous rectification. In practice, the driving chip 130 may be a PWM controller chip or the like.

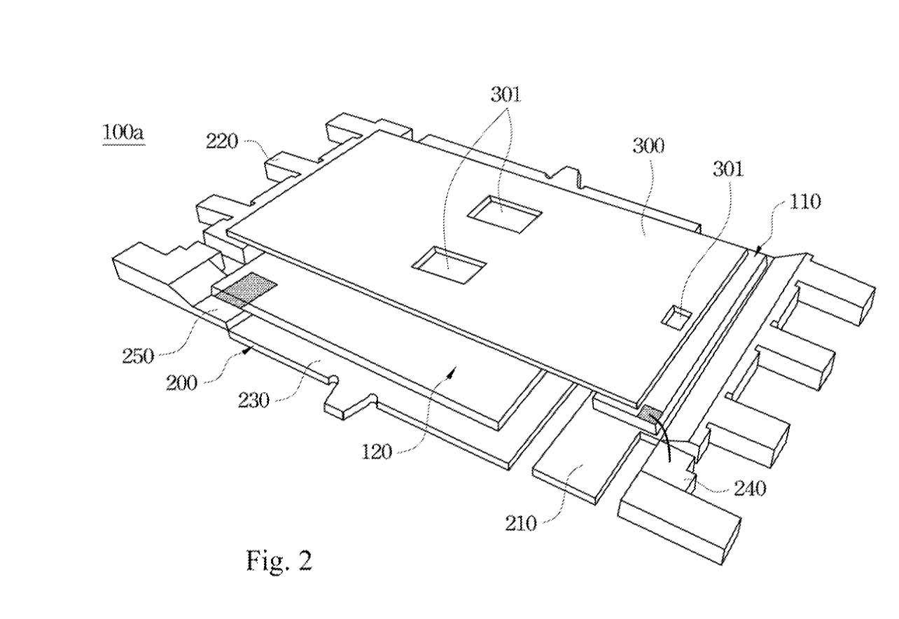

In configuration, a drain of the high-side power transistor M1 is electrically connected to a voltage plate 210 of a lead frame for receiving working voltage; a source of the low-side power transistor M2 is electrically connected to a ground plate 230 of the lead frame; a source of the high-side power transistor M1 and a drain of the low-side power transistor M2 both are connected to a output plate 220 of the lead frame for outputting voltage, in which the specific structure are shown in FIGS. 2-4.

FIG. 2 is a pictorial drawing of a power semiconductor package 100a according to one embodiment of the present disclosure. As shown in FIG. 2, the power semiconductor package 100a includes the lead frame 200, the first die 110 and the second die 120. The lead frame 200 has the voltage plate 210, the output plate 220, the ground plate 230, a first gate plate 240 and a second gate plate 250 separated from each other. The first die 110 is disposed on the voltage plate 210, and a gate of the high-side power transistor of the first die 110 is connected to the first gate plate 240. In this embodiment, the gate of the high-side power transistor is connected to the first gate plate 240 by wire bonding. The second die 120 is disposed on the ground plate 230. The source of the low-side power transistor of the second die 120 is on the lower surface of the second die 120 and is electrically connected to the ground plate 230. A gate of the low-side power transistor of the second die 120 is on the lower surface of the second die 120 and is connected to the second gate plate 250. In this embodiment, the second die 120 is mounted on the ground plate 230 by flip-chip bonding. In an alternative embodiment, the second die may be connected to the lead frame by wire bonding. In practice, those with ordinary skill in the art may flexibly choose the bonding manner depending on the desired application. The voltage plate 210 and the ground plate 230 can be adequately utilized for heat dissipation. In this way, a power layer and a ground layer of an external printed circuit board (PCB) are connected to the voltage plate 210 and ground plate 230 for increasing a heat dissipation area and a heat dissipation path, so as to improve an effect on the heat dissipation. In addition, the first die 110 and the second die 120 are connected without using a plurality of bonding wires, so that an inter-die distance can be very short, the bigger die can be disposed in the package and impedance can be further reduced.

In this embodiment, the low-side power transistor and high-side power transistor are vertical type power MOSFET which the gate and the source are on the same surface of the die and the drain is on another surface of it. Therefore, in this embodiment of the power semiconductor package, the vertical type power MOSFETs with low-complexity manufacturing process can be chosen as the low-side power transistor and the high-side power transistor for lowering the manufacturing cost.

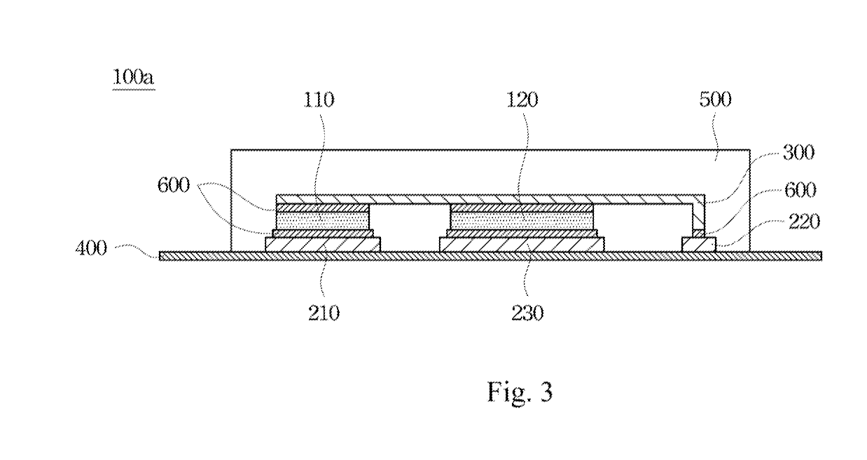

FIG. 3 is a lateral view of FIG. 2 according to one embodiment of the present disclosure. As shown in FIG. 3, the power semiconductor package 100a includes a single connecting strip 300. The connecting strip 300 is disposed on the first die 110, the second die 120 and the output plate 220, and is electrically connected to the source of the high-side power transistor M1 and the drain of the low-side power transistor M2, as shown in FIG. 1. In this way, the top of the first die 110 and the top of the second die 120 with common electrical potential can be electrically connected through this single connecting strip 300, so as to improve heat dissipation, reduce line inductance and increase a working frequency. Moreover, the connecting strip 300 has a location hole 301 as shown in FIG. 2, and thus, the connecting strip 300 can be aligned to the top of the first die 110 and the top of the second die 120 in position.

In FIG. 3, the connecting strip 300 is a single metal clip. The metal clip is adhered to the first die 110, the second die 120 and the output plate 220 by using solder 600. The power semiconductor package 100a further includes an encapsulating layer 500. The first die 10 and the second die 120 are covered with the encapsulating layer 500, so that the encapsulating layer 500 can prevent moisture from corroding the dies to improve reliability.

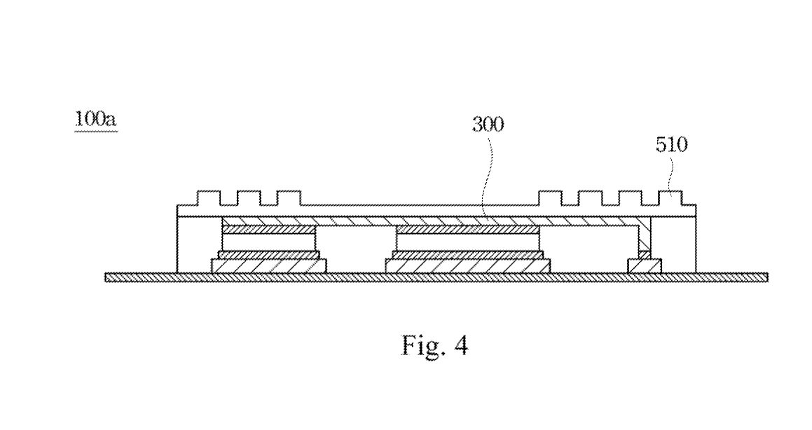

FIG. 4 is a lateral view of FIG. 2 according to another embodiment of the present disclosure. As shown in FIG. 4, a top of the metal clip 300 is exposed to outside the encapsulating layer 500 for improving heat dissipation. Moreover, the power semiconductor package 100a may include a heat dissipation plate. The heat dissipation plate 510 is in direct contact with the top of the metal clip 300 for further improving heat dissipation.

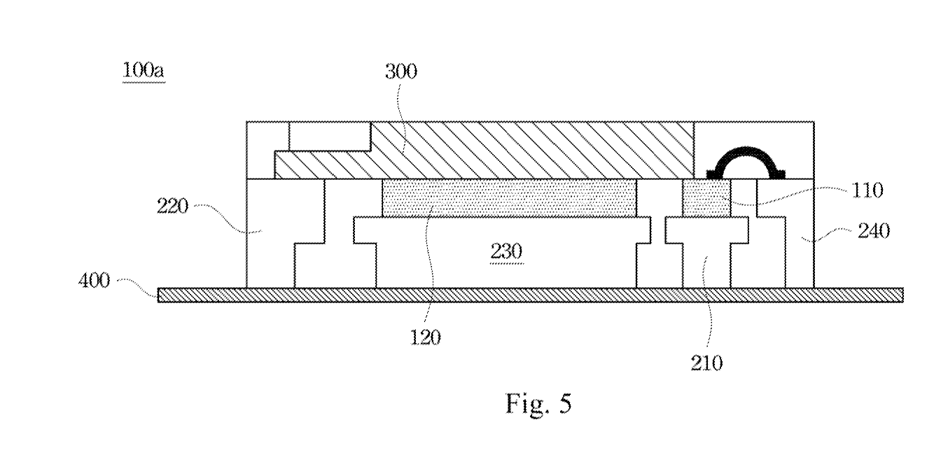

FIG. 5 is a lateral view of FIG. 2 according to yet another embodiment of the present disclosure. As shown in FIG. 5, the voltage plate 210 and the ground plate 230 disposed on the printed circuit hoard 400 can dissipate heat from the first die 110 and the second die 120; the metal clip 300 disposed on the first die 110 and the second die 120 also can dissipate heat from the first die 110 and the second die 120. Thus, the power semiconductor package 100a has a double-sided cooling effect.

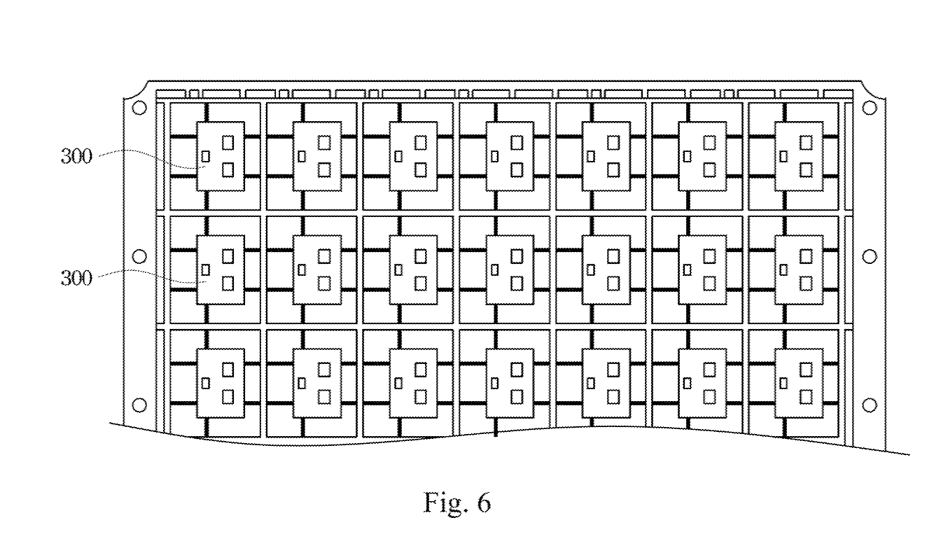

FIG. 6 is a partial schematic diagram of a one-piece plate having a plurality of metal clips according to one embodiment of the present disclosure. Basically, one metal clip is for one package. However, in practice, the one-piece plate having a plurality of metal clips 300 are as shown in FIG. 6, wherein the number of the metal clips 300 is equal to the number of the lead frames. First, dies are disposed on each lead frame, and solder is applied thereto. Then, the one-piece plate having a plurality of metal clips is aligned to the lead frames in position and then is pressed on the lead frames. Then, a cutting process is performed to product a plurality of power semiconductor package. Thus, manufacturing time can be reduced.

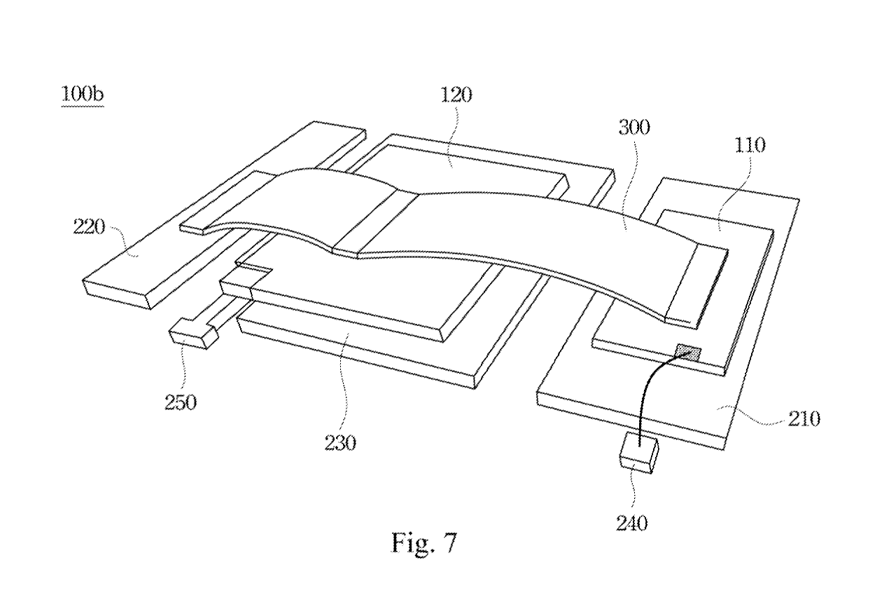

FIG. 7 is a pictorial drawing of the power semiconductor package according to another embodiment of the present disclosure. As shown in FIG. 7, the first gate plate 240 and the second gate plate 250 are positioned along the same side of the first and second dies 110 and 120 for a specific use. In contrast, in FIG. 2, the first gate plate 240 and the second gate plate 250 are positioned at two sides of the first and second dies 110 and 120.

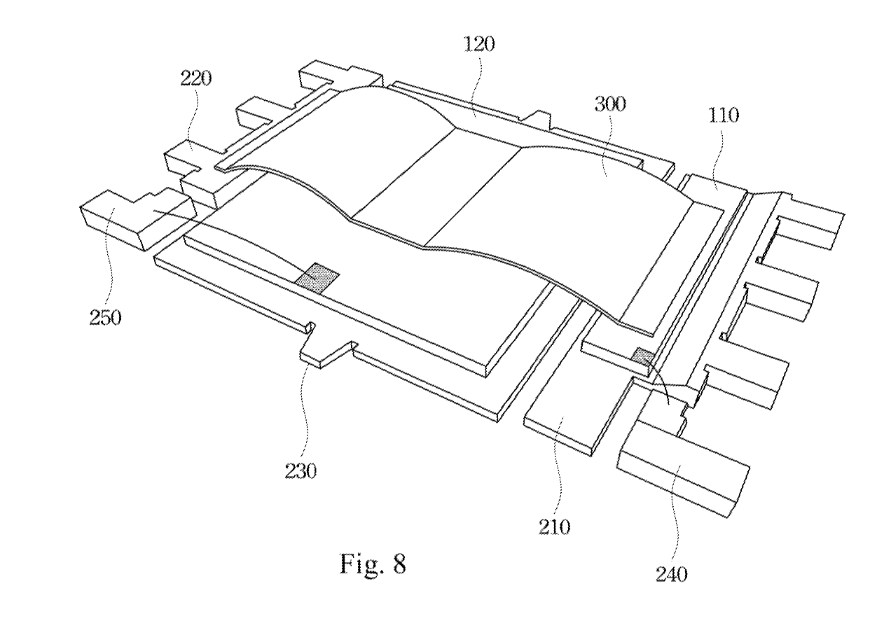

FIG. 8 is a pictorial drawing of the power semiconductor package according to yet another embodiment of the present disclosure. The gate of the low-side power transistor is on the lower surface of the second die 120 in FIG. 7. Its different to the embodiment in FIG. 7, the embodiment in FIG. 8 is that the gate of the low-side power transistor is on the upper surface of the second die 120 and connected to the second gate plate 250 by wire bounding. The source of the low-side power transistor is on the lower surface of the second die 120 and electrically connected to the ground plate 230. The drain of the low-side power transistor is on the upper surface of the second die 120 and electrically connected to the source of the high-side power transistor of the first die 100 by the single aluminium strip 300.

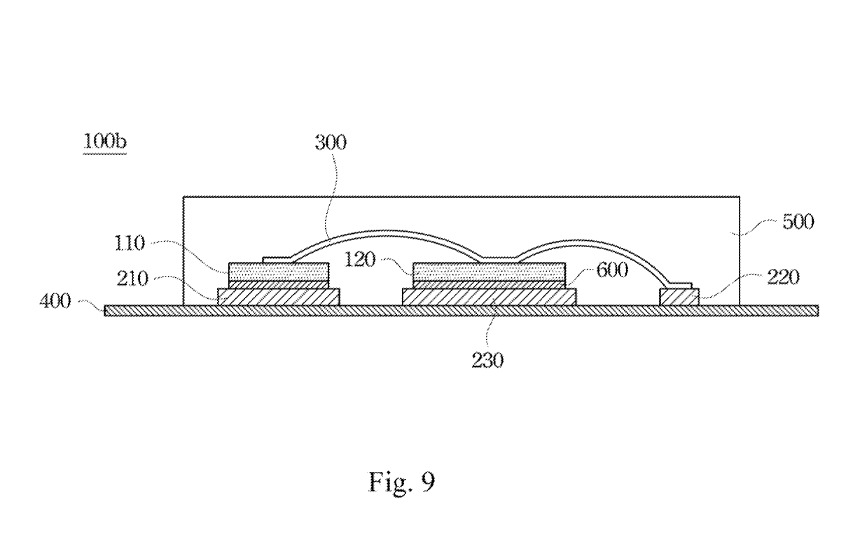

FIG. 9 is a lateral view of FIG. 7 according to one embodiment of the present disclosure. As shown in FIGS. 7 and 9, the connecting strip 300 is a single aluminium strip. The aluminium strip 300 is connected to the first die 110, the second die 120 and the output plate 220 by thermal compression bonding without above-mentioned solder 600. Since the aluminium strip 300 is a flexible metal, there is a curve on the without compression portion of the aluminium strip 300. The length of the aluminium strip 300 may be increased for expanding the heat dissipation area. The area of the compression portion of the aluminium strip 300 may be regulated according to the designing demand. The aluminium strip is an example in this embodiment and the disclosure is not limited thereto. In an alternative embodiment, the connecting strip 300 may be a flexible conducting material.

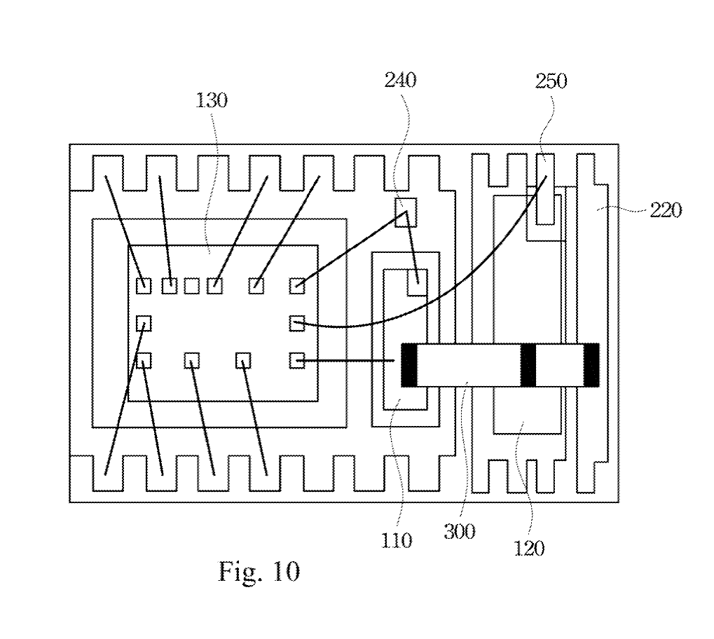

FIG. 10 is a top view of the power semiconductor package according to another embodiment of the present disclosure. As shown in FIG. 10, the driving chip 130 can be integrated into the power semiconductor package, and therefore the power semiconductor package may further include the driving chip 130. The driving chip 130 is connected to the first gate plate 240, the second gate plate 250 and the first die 110.

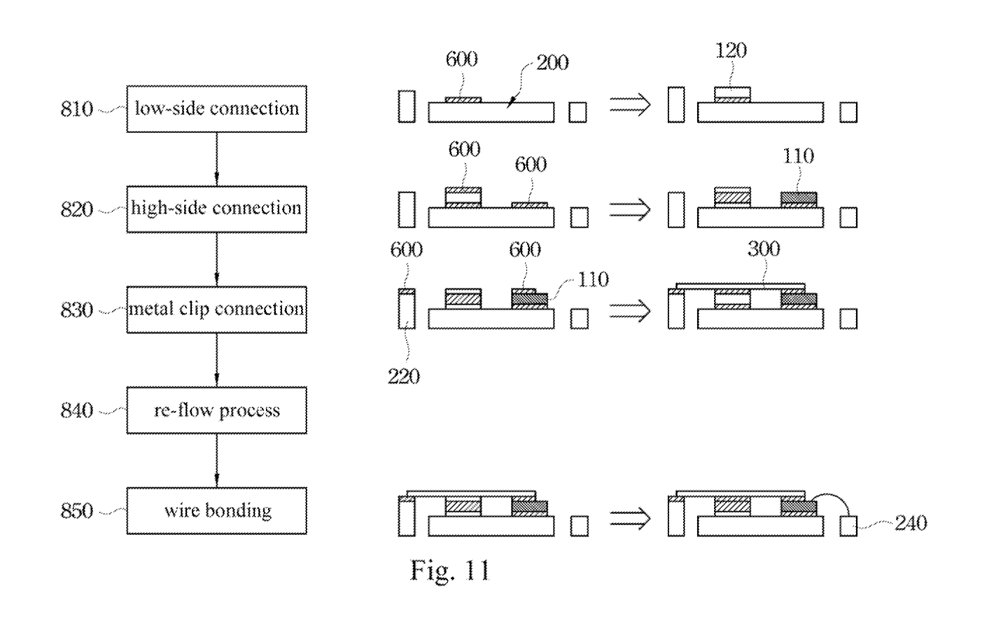

FIG. 11 is a schematic diagram of a method of manufacturing the power semiconductor package according to another embodiment of the present disclosure. In this method, the steps are not recited in the sequence in which the steps are performed. That is, unless the sequence of the steps is expressly indicated, the sequence of the steps is interchangeable, and all or part of the steps may be simultaneously, partially simultaneously, or sequentially performed.

As shown in FIG. 11, in step 810 for low-side connection, the lead frame 200 is provided, and solder 600 is applied thereto; then, the second die 120 is disposed on the ground plate of the lead frame 200, and a gate of the low-side power transistor of the second die 120 is connected to the second gate plate. In step 820 for high-side connection, solder 600 is applied first, and then the first die 110 is disposed on the voltage plate. In step 830 for the metal clip, solder 600 is applied first, and then the metal clip that acts as the connecting strip 300 is disposed on the first die 110, the second die 120 and the output plate 220. Step 840 is a re-flow process for clearing remaining portions of solder 600. In step 850, the gate of the high-side power transistor of the first die 110 is connected to the first gate plate 240 by wire bonding. In present invention, only one re-flow process is needed, so as to reduce the manufacturing time.

In FIG. 11, step 810 is performed before step 820. In an alternative embodiment, step 820 is performed before step 810. In practice, those with ordinary skill in the art may flexibly choose the sequence depending on the desired application.

In step 810, the second die 120 is mounted on the ground plate of the lead frame 200 by flip-chip bonding.

The manufacturing method may include the step of forming an encapsulating layer, so that the first die 10 and the second die 120 can be covered with the encapsulating layer.

In addition, the top of the metal clip is exposed to outside the encapsulating layer, and the manufacturing method further includes the step of using a heat dissipation plate is in direct contact with the top of the metal clip.

An alternative step may replace step 830. In this alternative step, a single aluminium strip can act as the connecting strip, and the aluminium strip is connected to the first die 110, the second die 120 and the output plate 220 by thermal compression bonding.

The manufacturing method may include the step of providing the driving chip 130 that is connected to the first gate plate and the second gate plate, as shown in FIG. 10.

The readers attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

What is claimed is:

1. A power semiconductor package comprising:
a lead frame having a voltage plate, a ground plate, an output plate, a first gate plate and a second gate plate separated from each other;
a first die disposed on the voltage plate, the first die having a high-side power transistor disposed therein, a gate of the high-side power transistor connected to the first gate plate;
a second die disposed on the ground plate, the second die having a low-side power transistor disposed therein, a gate of the low-side power transistor connected to the second gate plate; and
a single connecting strip disposed on the first die, the second die and the output plate, and electrically connected to a source of the high-side power transistor and a drain of the low-side power transistor.

2. The power semiconductor package of claim 1, wherein the connecting strip is a flexible conducting material.

3. The power semiconductor package of claim 2, wherein the connecting strip is a single aluminium strip connected to the first die, the second die and the output plate by thermal compression bonding.

4. The power semiconductor package of claim 2, wherein the connecting strip is in direct contact with the first die, the second die and the output plate.

5. The power semiconductor package of claim 1, wherein the second die is mounted on the ground plate by flip-chip bonding.

6. The power semiconductor package of claim 1, wherein the gate of the high-side power transistor is connected to the first gate plate by wire bonding.

7. The power semiconductor package of claim 1, further comprising:
an encapsulating layer, wherein the first die and the second die covered with the encapsulating layer.

8. The power semiconductor package of claim 1, wherein the connecting strip is a single metal clip adhered to the first die, the second die and the output plate.

9. The power semiconductor package of claim 8, wherein a top of the metal clip is exposed to outside the encapsulating layer and the power semiconductor package further comprises:
a heat dissipation plate in direct contact with the top of the metal clip.

10. The power semiconductor package of claim 8, wherein the connecting strip has a location hole.

11. The power semiconductor package of claim 1, wherein the first gate plate and the second gate plate are positioned at two sides of the first and second dies.

12. The power semiconductor package of claim 1, wherein the first gate plate and the second gate plate are positioned along the same side of the first and second dies.

13. The power semiconductor package of claim 1 further comprising:
a driving chip connected to the first gate plate and the second gate plate.

14. The power semiconductor package of claim 1, wherein a source of the low-side power transistor is on a lower surface of the second die and the drain of the low-side power transistor is on an upper surface of the second die.

15. The power semiconductor package of claim 14, wherein the low-side power transistor and high-side power transistor are vertical type power MOSFET and the gate of the low-side power transistor is on the lower surface of the second die.

16. The power semiconductor package of claim 14, wherein the gate of the low-side power transistor is on the upper surface of the second die and connected to the second gate plate by wire bounding.

17. A method of manufacturing a power semiconductor package, the method comprising:
providing a lead frame having a voltage plate, a ground plate, an output plate, a first gate plate and a second gate plate;
positioning a first die disposed on the voltage plate;
positioning a second die disposed on the ground plate, and connecting a gate of a low-side power transistor of the second die to the second gate plate;
positioning a single connecting strip on the first die, the second die and the output plate, and electrically connecting the connecting strip to a source of the high-side power transistor and a drain of the low-side power transistor; and
connecting a gate of a high-side power transistor of the first die to the first gate plate.

18. The method of claim 17, wherein the second die is mounted on the ground plate by flip-chip bonding.

19. The method of claim 17 wherein the step of positioning the single connecting strip comprises:
providing a single metal clip as the connecting strip, and adhering the metal clip to the first die, the second die and the output plate.

20. The method of claim 17, wherein the step of positioning the single connecting strip comprises:
providing a single aluminium strip as the connecting strip, and connecting the single aluminium strip to the first die, the second die and the output plate by thermal compression bonding.
